(19) United States
(12) Patent Application Publication
(10) Pub. No.: US 2016/0172164 A1
(43) Pub. Date: Jun. 16, 2016

(54) REMOTE DELIVERY OF CHEMICAL REAGENTS

(71) Applicant: Entegris, Inc., Billerica, MA (US)

(72) Inventors: Joseph D. Sweeney, New Milford, CT (US); Edward E. Jones, Woodbury, CT (US); Oleg Byl, Southbury, CT (US); Ying Tang, Brookfield, CT (US); Joseph R. Despres, Middletown, CT (US); Steven E. Bishop, Corrales, NM (US)

(73) Assignee: Entegris, Inc., Billerica, MA (US)

(21) Appl. No.: 14/906,537

(22) PCT Filed: Jul. 21, 2014
(86) PCT No.: PCT/US2014/047410

§ 371 Date: Jan. 20, 2016

Related U.S. Application Data
(60) Provisional application No. 61/857,587, filed on Jul. 23, 2013.

(51) Int. Cl. H01J 37/32

(52) U.S. Cl. CPC H01J 37/32449; H01J 2237/006; H01J 2237/08; H01J 2237/24564; H01J 2237/002; H01J 2237/3365

(57) ABSTRACT

Fluid storage and dispensing systems and methods for remote delivery of fluids are described, for providing fluid from a source vessel at lower voltage to one or more fluid-utilizing tools at higher voltage, so that the fluid crosses the associated voltage gap without arcing, discharge, premature ionization, or other anomalous behavior, and so that when multiple fluid-utilizing tools are supplied by the remote source vessel, fluid is efficiently supplied to each of the multiple tools at suitable pressure level during the independent operation of others of the multiple vessels.

### CROSS-REFERENCE TO RELATED APPLICATION

The benefit of priority of U.S. Provisional Patent Application No. 61/857,587 filed Jul. 23, 2013 in the names of Joseph D. Sweeney, Edward E. Jones, Oleg Byl, Ying Tang, Joseph R. Despres, and Steven E. Bishop for “Remote Delivery of Chemical Reagents” is hereby claimed under the provisions of 35 USC 119. The disclosure of U.S. Provisional Patent Application No. 61/857,587 is hereby incorporated herein by reference, in its entirety, for all purposes.

### FIELD

The present disclosure relates to remote delivery systems and methods for supplying fluids, e.g., chemical reagents, to industrial process facilities such as semiconductor manufacturing plants including ion implantation apparatus. The present disclosure further relates to systems and methods for remotely supplying dopant source gas to an ion implanter for use in the doping of materials such as semiconductor, photovoltaic, and flat panel substrates, and to ion implantation systems utilizing such remote supply systems and methods.

### DESCRIPTION OF THE RELATED ART

Ion implantation is a basic unit operation in the manufacture of microelectronic device products. Consistent with the fundamental character and ubiquity of ion implantation operations in semiconductor manufacturing facilities, substantial efforts have been and continue to be made to improve the efficiency and effectiveness of ion implanter equipment.

Since almost all conventional dopant feedstock gases used in ion implantation are of a highly toxic and hazardous character, the foregoing efforts have included a focus on the objective of enhancing safety in the supply, handling and use of dopant source materials.

During the last 15 years, the commercialization and widespread deployment in ion implantation systems of physical adsorbent-based fluid storage and dispensing vessels of a type available from ATMI, Inc. (Danbury, Conn., USA) under the trademark SDS have made a major contribution to such safety enhancement efforts. By providing a physical adsorbent medium in the fluid storage and dispensing vessel as a storage medium for toxic and hazardous dopant source fluids such as arsine, phosphine, silane and boron trifluoride, such fluids can be sorptively retained in the vessel at low, e.g., subatmospheric, pressures and readily desorbed from the physical adsorbent under dispensing conditions.

Such low pressure storage and dispensing vessels thus overcome the dangers incident to the use of high pressure gas cylinders holding the same dopant source fluids at high super-atmospheric pressures on the order of 3,000 to 15,000 kPa. These dangers include the potential for catastrophic dispersion of highly pressurized toxic/hazardous fluids in the event of a rupture of the cylinder body or failure of a valve head assembly of the high pressure gas cylinder.

Ion implantation systems are characteristically configured with a gas box, an ion source unit for ionization of the dopant feedstock gas, an implanter including accelerator and magnetic separation components, and associated flow circuitry and instrumentation. In typical ion implantation systems, the dopant gas supply vessels are located in the gas box of the system. The gas box is an enclosure connected to and at the same high voltage as the ion source unit in operation.

In this conventional ion implantation system configuration, the supply vessels containing the toxic/hazardous dopant feedstock gas have to be periodically changed out and replaced by fresh vessels charged with the dopant source gas. To perform such change-out of gas supply vessels located inside the ion implantation system gas box, technicians must don self-contained breathing apparatus (SCBA) units, physically remove depleted supply vessels from the gas box and install fresh vessels in the gas box. In conducting the change-out operation, the vicinity of the ion implantation system in the semiconductor manufacturing facility must be cleared of personnel other than the SCBA-equipped technicians, in order to accommodate the risks associated with the change-out operation.

In addition to the dangers associated with such change-out of dopant source gas supply vessels in the ion implantation system, it also is a common occurrence that dopant source gas supply vessels become depleted at inconvenient times during production operations, so that the ion implantation system must be shut down. Such unscheduled shutdown of the ion implantation system can require expensive reworking of partially processed wafers, and in some cases the wafer products may be deficient or even useless for their intended purpose, as a consequence of the interruption of their processing. Such events can in turn seriously adversely affect the ion implanter system and the economics of the semiconductor manufacturing facility in which such ion implanter system is located.

The art continues to pursue the development of safer gas packaging and delivery, to provide safe, effective and reliable sources of gas for industrial fluid-utilizing processes. In consequence, the art continues to seek improvements in remote delivery of chemical reagents.

### SUMMARY

The present disclosure relates to remote delivery systems and methods for supplying fluids to industrial process facilities such as semiconductor manufacturing plants including ion implantation apparatus.

In one aspect, the disclosure relates to a fluid supply system for delivery of fluid from a fluid supply source vessel at a relatively lower voltage to at least one fluid-utilizing tool at a relatively higher voltage wherein the fluid passes through a corresponding voltage differential, said fluid supply system comprising the fluid supply source vessel, and at least one fluid management apparatus selected from the group consisting of:
(a) a fluid delivery flow circuit comprising a fluid delivery line adapted for coupling to the fluid supply vessel to flow fluid from the fluid supply vessel through the voltage differential to the fluid-utilizing tool, a dielectric interface adapted for coupling to the fluid delivery line to separate lower voltage and higher voltage segments of the fluid delivery line from one another, a first pressure regulator and a flow control component or assembly in the lower voltage segment of the fluid delivery line, a second pressure regulator in the higher voltage segment of the fluid delivery line, wherein the first and second pressure regulators are adapted to regulate pressure of fluid flowed through the fluid delivery line from the fluid supply vessel to the fluid-utilizing tool to reduce pressure variation of fluid flowed to the fluid-utilizing tool;
(b) an electric current monitor adapted to monitor current in the fluid supply source vessel and output a signal correlative to said current in an event of electrical disturbance mediating arcing, discharge, or premature ionization of the fluid in a fluid delivery flow circuit when coupled to the fluid delivery source vessel, and an interlock system adapted to receive the signal from the electric current monitor in said event of electrical disturbance, and responsively actuate a remedial action to abate the electrical disturbance or ameliorate an effect thereof;
(c) a fluid delivery flow circuit comprising a non-linear fluid delivery line adapted for coupling to the fluid supply vessel, to provide a non-linear extended length flow path for flow of fluid from the fluid supply vessel through the voltage differential to a fluid-utilizing tool, to suppress arcing, discharge, or premature ionization of the fluid;
(d) a fluid delivery flow circuit comprising a fluid delivery line adapted for coupling to the fluid supply vessel to flow fluid from the fluid supply vessel through the voltage differential to the fluid-utilizing tool, the fluid delivery line being in fluid communication with a reversible sorbent medium having sorptive affinity for said fluid and arranged to sorptively/desorptively modulate fluid flow through the fluid delivery line to prevent fluid supply interruptions;
(e) a control system adapted to monitor and control supply pressure and/or the demand flow rate of fluid flowed from the fluid supply vessel to the fluid-utilizing tool to reduce pressure variation of fluid flowed to the fluid-utilizing tool;
(f) a thermal control system adapted to heat or cool fluid flowed from the fluid supply vessel to the fluid-utilizing tool, at sufficient rate to control fluid pressure so as to reduce pressure variation of fluid flowed to the fluid-utilizing tool;
(g) a fluid delivery flow circuit comprising a fluid delivery line adapted for coupling to the fluid supply vessel to flow fluid from the fluid supply vessel through the voltage differential to the fluid-utilizing tool, and a surge chamber coupled to the fluid delivery line and adapted to receive fluid from the fluid delivery line so as to provide a gas reservoir to prevent gas supply interruptions; and
(h) an on-board vessel associated with the fluid-utilizing tool and at the relatively higher voltage thereof during operation of the fluid-utilizing tool, said on-board vessel being adapted for filling by said fluid supply source vessel during said operation or between successive periods of said operation, and if adapted to be filled during said operation, then comprising at least one fluid management apparatus (a)-(g).

In another aspect, the disclosure relates to a method of delivering fluid at relatively lower voltage to a fluid-utilizing tool at relatively higher voltage, wherein the fluid passes through a corresponding voltage differential, such method comprising operating a fluid supply system as variously described herein.

In a further aspect, the disclosure relates to a method of providing for use in a manufacturing facility comprising a fluid-utilizing tool operated at elevated voltage, a fluid supply system as variously described herein.

Other aspects, features and embodiments of the disclosure will be more fully apparent from the ensuing description and appended claims.

### BRIEF DESCRIPTION OF THE DRAWINGS

FIG. 1 is a schematic representation of an ion implantation system utilizing a dopant feed gas supply arrangement according to one embodiment of the present disclosure.

FIG. 2 is a schematic representation of an ion implantation system utilizing a dopant feed gas supply arrangement according to another embodiment of the present disclosure.

FIG. 3 is a schematic representation of an ion implantation system utilizing a dopant feed gas supply arrangement according to another embodiment of the present disclosure.

FIG. 4 is a schematic representation of an ion implantation system utilizing a dopant feed gas supply arrangement according to a further embodiment of the present disclosure.

FIG. 5 is a schematic representation of an auto-switching sub-atmospheric pressure gas delivery system according to one embodiment of the present disclosure.

FIG. 6 is a schematic representation of an auto-switching assembly according to another embodiment of the present disclosure.

### DETAILED DESCRIPTION

The present disclosure relates to systems, apparatus and methods for supplying dopant source gas to an ion implantation system in a manner that enhances the operational efficiency and on-stream time of the ion implantation system. The present disclosure further relates to ion implantation systems, apparatus and methods that effect safe remote delivery of gases to the ion implanter.

As used herein and in the appended claims, the singular forms “a”, “and”, and “the” include plural referents unless the context clearly dictates otherwise.

The disclosure, as variously set out herein in respect of features, aspects and embodiments thereof, may in particular implementations be constituted as comprising, consisting, or consisting essentially of, some or all of such features, aspects and embodiments, as well as elements and components thereof being aggregated to constitute various further implementations of the disclosure. The disclosure correspondingly contemplates such features, aspects and embodiments, or a selected one or ones thereof, in various permutations and combinations, as being within the scope of the present disclosure.

In embodiments, the disclosure relates to dopant source gas supply in ion implantation systems, in which the dopant source gas is provided to the ion implantation system from a remote supply vessel in a manner providing safe and efficient crossing of the voltage gap.

In typical ion implantation systems, the dopant gas supply vessels are located in the gas box of the ion implantation system. The gas box is an enclosure that is structurally associated with, and at the same high voltage as, the ion source unit in operation. If the dopant source gas supply is remote from the ion implanter, there will be a potential difference between the electrical potential that exists within the implanter and the electrical potential that exists in the dopant source gas supply. Thus, when the gas arrives at the implanter from the dopant source gas supply, the gas must cross a high voltage gap, e.g., from 1 kV to up to megavolts for a high energy implanter. Crossing such voltage gap is a safety concern due to possible arcing or discharge that may occur, particularly while operating with toxic, flammable or corrosive gases.

The present disclosure provides systems, methods, and apparatus that achieve efficiency and safety in the delivery of dopant source gas from a location outside the implanter tool enclosure. In a dopant source gas supply system for an ion implantation system as herein disclosed, the system comprises a dopant source gas supply vessel that is adapted to be positioned in remote relationship to the ion implantation system. Such dopant source gas supply vessel may be of any type suitable for storage and dispensing of the fluid or chemical reagent to be used.

In one embodiment, the dopant source gas supply vessel comprises a pressure-regulated gas storage and dispensing vessel. Pressure-regulated gas storage and dispensing vessels have been developed in which fluid is contained in a vessel having a fluid pressure regulator disposed in its interior volume (wherein the regulator is referred to as an “internal regulator”). Such arrangement is effective to permit fluid to be stored at high pressures, with the regulator being operative to discharge fluid from the vessel only when exposed to a downstream pressure that is below the set point of the regulator. Such internally disposed regulator systems are more fully described in Wang et al. U.S. Pat. Nos. 6,101,816 and 6,089,027, and are commercially available from ATMI, Inc. (Danbury, Conn., USA) under the trademark VAC.

Pressure-regulated vessels of such type can be arranged with appropriate set point pressures of the internal regulators, to provide low pressure dopant source gas to the corresponding ion implantation system, to provide enhanced safety in the dispensing of the dopant source gas to the associated ion implantation system tools. By way of illustration, the supply vessel may be pressure regulated to supply dopant source gas to the ion implanter at pressure in a range of from 65 to 90 kPa.

In another embodiment, the dopant source gas supply vessel comprises a gas storage and dispensing vessel containing a physical adsorbent having sorptive affinity for the dopant source gas. Such gas storage and dispensing vessels are described in Tom et al. U.S. Pat. No. 5,518,528, in which gas is adsorbed and stored on a physical adsorbent in a fluid storage and dispensing vessel and is desorbed from the adsorbent and discharged from the vessel under dispensing conditions. In these systems, the gas can be stored and dispensed at sub-atmospheric pressure levels, typically below about 700 torr. Physical adsorbent-based systems of such type are commercially available from ATMI, Inc. (Danbury, Conn., USA) under the trademarks SDS and SAGE.

The source gas supply apparatus of the present disclosure can be adapted for use with any suitable dopant source gas or with a cleaning material for in-line cleaning of the ion implantation system, e.g., cleaning agents such NF₃ or XeF₂. For example, the dopant source material may include a dopant source gas selected from the group consisting of arsine, phosphine, boron trifluoride, diboron tetrafluoride, germane, diborane, carbon monoxide, carbon dioxide, germanium tetrafluoride, silicon tetrafluoride, and silane. The present disclosure contemplates mixtures of dopant materials, as well as dopant source gas compositions containing a co-flow agent in addition to the dopant source gas. The co-flow agent may include gas species to enhance the nature and extent of the ionization of the dopant source gas, to effect cleaning of the ion implantation system, or otherwise to benefit the operation of the ion implantation system and ion implantation processes carried out therein. In one embodiment, the co-flow agent includes xenon difluoride, to effect in situ cleaning of the ion source. In other embodiments, the co-flow agent may include one or more of hydrogen, halogen (e.g., fluorine or other fluoro species), oxygen, methane, ammonia, inert gas species, etc.

When delivering the dopant source gas from a remote delivery location, a less toxic dopant source gas may be selected to increase the safety of the overall operation. By way of example, in place of phosphorus and arsenic hydrides such as phosphine and arsine, phosphorus and arsenic fluorides such as PF₃, PF₅, AsF₅, or AsF₃ may be suitable for remote delivery in accordance with the present disclosure. The use of fluorides reduces flammability hazards and increases some health hazard indices. In various embodiments, the fluorides may be used with co-flow agents such as hydrogen, ammonia or other less flammable hydrogen-containing gases. In other embodiments, the fluorides may be used in mixture with hydrogen, ammonia or other less flammable hydrogen-containing gases.

The present disclosure contemplates a fluid supply system for delivery of fluid from a fluid supply source vessel at a relatively lower voltage to at least one fluid-utilizing tool at a relatively higher voltage wherein the fluid passes through a corresponding voltage differential. Such fluid supply system comprises the fluid supply source vessel, and at least one fluid management apparatus selected from the group consisting of:
(a) a fluid delivery flow circuit comprising a fluid delivery line adapted for coupling to the fluid supply vessel to flow fluid from the fluid supply vessel through the voltage differential to the fluid-utilizing tool, a dielectric interface adapted for coupling to the fluid delivery line to separate lower voltage and higher voltage segments of the fluid delivery line from one another, a first pressure regulator and a flow control component or assembly in the lower voltage segment of the fluid delivery line, a second pressure regulator in the higher voltage segment of the fluid delivery line, wherein the first and second pressure regulators are adapted to regulate pressure of fluid flowed through the fluid delivery line from the fluid supply vessel to the fluid-utilizing tool to reduce pressure variation of fluid flowed to the fluid-utilizing tool;
(b) an electric current monitor adapted to monitor current in the fluid supply source vessel and output a signal correlative to said current in an event of electrical disturbance mediating arcing, discharge, or premature ionization of the fluid in a fluid delivery flow circuit when coupled to the fluid delivery source vessel, and an interlock system adapted to receive the signal from the electric current monitor in said event of electrical disturbance, and responsively actuate a remedial action to abate the electrical disturbance or ameliorate an effect thereof;
(c) a fluid delivery flow circuit comprising a non-linear fluid delivery line adapted for coupling to the fluid supply vessel, to provide a non-linear extended length flow path for flow of fluid from the fluid supply vessel through the voltage differential to a fluid-utilizing tool, to suppress arcing, discharge, or premature ionization of the fluid;
(d) a fluid delivery flow circuit comprising a fluid delivery line adapted for coupling to the fluid supply vessel to flow fluid from the fluid supply vessel through the voltage differential to the fluid-utilizing tool, the fluid delivery line being in fluid communication with a reversible sorbent medium having sorptive affinity for said fluid and arranged to sorptively/desorptively modulate fluid flow through the fluid delivery line to prevent fluid supply interruptions;
(e) a control system adapted to monitor and control supply pressure and/or the demand flow rate of fluid flowed from the fluid supply vessel to the fluid-utilizing tool to reduce pressure variation of fluid flowed to the fluid-utilizing tool;
(f) a thermal control system adapted to heat or cool fluid flowed from the fluid supply vessel to the fluid-utilizing tool, at sufficient rate to control fluid pressure so as to reduce pressure variation of fluid flowed to the fluid-utilizing tool;
(g) a fluid delivery flow circuit comprising a fluid delivery line adapted for coupling to the fluid supply vessel to flow fluid from the fluid supply vessel through the voltage differential to the fluid-utilizing tool, and a surge chamber coupled to the fluid delivery line and adapted to receive fluid from the fluid delivery line so as to provide a gas reservoir to prevent gas supply interruptions; and
(h) an on-board vessel associated with the fluid-utilizing tool and at the relatively higher voltage thereof during operation of the fluid-utilizing tool, said on-board vessel being adapted for filling by said fluid supply source vessel during said operation or between successive periods of said operation, and if adapted to be filled during said operation, then comprising at least one fluid management apparatus (a)-(g).

The fluid supply system may be constituted, with the fluid-utilizing tool comprising an ion implantation tool. The fluid supply source vessel in such circumstance may be located outside of a housing of the ion implantation tool. The fluid supply source vessel may be remote from the fluid-utilizing tool, i.e., may be in physically spaced apart relationship to such tool. For example, the fluid supply source vessel may be physically separated from the fluid-utilizing tool by distance of at least 0.6 m, e.g., distance in a range of from 0.6 m to 100 m.

As discussed above, the fluid supply source vessel may comprise a pressure-regulated fluid supply source vessel, or alternatively an adsorbent-based fluid supply source vessel, or alternatively a pressure-regulated fluid supply source vessel containing adsorbent medium in an interior volume thereof, or any other suitable type of fluid supply source vessel.

In addition to being of any suitable fluid supply source vessel type, the fluid supply source vessel may be adapted to supply fluid at any suitable pressure to the fluid-utilizing tool. For example, the fluid supply source vessel may be adapted to supply fluid at subatmospheric pressure, atmospheric pressure, or low superatmospheric pressure for delivery to the fluid-utilizing tool. In some embodiments, the fluid supply source vessel may be adapted to supply fluid at low superatmospheric pressure in a range of 780 Torr to 1800 Torr (104 kPa to 240 kPa). In other embodiments, the vessel may be adapted to dispense fluid at subatmospheric pressure in a range of from 10 Torr to 750 Torr (1.33 kPa to 100 kPa).

The fluid supply source vessel may define an interior volume for a fluid storage, and the interior volume may contain a fluid storage medium from which the fluid is released under dispensing conditions. The fluid storage medium may comprise physical adsorbent, ionic liquid, reversible chemisorbent medium, and/or other media in or on which the fluid may be stored under non-dispensing conditions, and from which the fluid may be flowed out of the vessel under dispensing conditions. The interior volume may also contain fluid management components for controllable release of fluid from the vessel, e.g., at a predetermined or otherwise desired pressure, flow rate, etc. such fluid management components may be of any suitable type, and may for example include fluid pressure regulators, flow control valves, such as check valves, vacuum-actuated valves, poppet valves, etc., frits, filters, flow restrictors, capillary devices, permselective membranes, contaminant getters, and any other fluid management components appropriate to dispensing of fluid of specific types and/or dispensed fluid characteristics.

In specific embodiments, the fluid supply source vessel may comprise an adsorbent-based fluid supply source vessel, containing adsorbent, e.g., carbon adsorbent, in a monolithic, granular, or other appropriate form. In other embodiments, the fluid supply source vessel may comprise a vessel having disposed in the interior volume thereof one, two, or more pressure regulator devices enabling the vessel to store liquid at elevated superatmospheric pressure and to dispense fluid at substantially lower pressure, e.g., subatmospheric pressure, atmospheric pressure, or superatmospheric pressure that is substantially lower than the elevated storage pressure of fluid in the vessel. In still other embodiments, the fluid supply source vessel may comprise a flow-limiting fluid supply source vessel containing in its interior volume flow-limiting components such as check valves, pressure-actuated valves, capillary flow restrictor components, and combinations thereof. In yet other embodiments, the fluid supply source vessel may comprise conventional high-pressure cylinders in which the fluid is contained at elevated superatmospheric pressure, e.g., 200 psig to 2000 psig (1.37 MPa to 13.8 MPa).

The fluid supply system of the present disclosure may comprise multiple fluid supply source vessels that are arranged for auto-switching upon exhaustion to a predetermined extent of an active dispensing one of multiple vessels, so that it is switched out with a fresh vessel containing fluid being switched into the dispensing flow circuitry, to thereby provide for uninterrupted fluid supply operation. Any suitable auto-switching assembly may be employed for such purpose.

In one embodiment, the auto-switching assembly comprises:
(a) a multiplicity of gas panels, each of which comprises gas flow circuitry including a product gas flow line coupleable to a fluid supply source vessel for flow of dispensed gas therethrough, a purge gas line coupleable to a purge gas source for flow of purge gas therethrough and optionally having a purge gas particle filter in the purge line, a pressure-controlled flow regulator in the product gas flow line, and selectively actuatable valves for selectively and independently isolating each of the product gas flow line and the purge gas line in the gas flow circuitry of the panel to prevent flow of gas therethrough;
(b) a product gas manifold interconnecting the product gas flow lines in each of the gas panels, for discharge of product gas from the product gas flow line of an active dispensing one of said gas panels;
(c) a purge gas manifold coupled in gas flow communication with the product gas flow lines and with the purge gas lines in each of the gas panels;
(d) a selectively actuatable evacuation driver arranged to exhaust gas from the flow circuitry of a non-dispensing one of said gas panels through said purge gas manifold; and
(e) a central processing unit (CPU) arranged to selectively actuate:
   (1) in each of the gas panels, the selectively actuatable valves, and
   (2) the selectively actuatable evacuation driver,
      so that each of the gas panels operates sequentially, alternatingly and repetitively in operational modes including (I) an active dispensing operational mode in which gas from the fluid supply source vessel is flowed through the product gas flow line to the product gas manifold, (II) a purging operational mode in which purge gas from the purge gas source is flowed through the purge gas line and into the product gas flow line and purge gas manifold, (III) an evacuation operational mode in which the purge gas line, product gas flow line and purge gas manifold are evacuated under action of the evacuation driver, and (IV) a fill transition to active gas dispensing condition operating mode in which the product gas flow line is filled with product gas from the product gas manifold and the pressure-controlled flow regulator in the product gas flow line operates to regulate flow of product gas from the fluid supply source vessel through the product gas flow line to the product gas manifold for re-initiation of (I) the active dispensing operational mode.

In another embodiment, the auto-switching assembly comprises
a gas dispensing manifold;
a plurality of fluid supply source vessels, each said fluid supply source vessel being joined to the gas dispensing manifold and including a vessel valve that is selectively openable to establish gas flow communication of the fluid supply source vessel with the gas dispensing manifold, and selectively closeable to terminate gas flow communication of the fluid supply source vessel with the gas dispensing manifold;
a plurality of flow control valves in the gas dispensing manifold, each associated with a corresponding one of the plurality of fluid supply source vessels and positioned in the manifold downstream from vessel valve of the associated fluid supply source vessel;
a plurality of bleed flow passages, each associated with a corresponding one of the flow control valves in the gas dispensing manifold and arranged to flow gas therethrough in bypassing relationship to the associated flow control valve, at a restricted low flow rate in relation to flow rate of gas through the associated flow control valve when the associated flow control valve is open and gas is flowed therethrough from an associated fluid supply source vessel; and
a controller arranged to selectively operate the flow control valves so that a flow control valve is opened only after (i) gas flow is established by opening a vessel valve of the associated fluid supply source vessel, and (ii) gas flow through the bleed flow passage associated with that flow control valve has caused gas pressure in the manifold to rise to an operating level for gas dispensing operation involving flow of gas out of the manifold.

The fluid supply source vessel when provided as an adsorbent-based vessel or other vessel adapted to dispense fluid at subatmospheric pressure may in various embodiments be integrated with a dispensing assembly coupled in gas flow communication with the vessel, and comprising a motive fluid driver arranged to effect extraction of fluid from the vessel, and flow of fluid through the dispensing assembly. The dispensing assembly may for example comprise a motive fluid driver comprising a device selected from the group consisting of pumps, blowers, fans, turbines, compressors, venturis, eductors, pressure-building circuits, bellows, diaphragms, peristaltic roller circuits, thermally-coupled gas expansion drivers, and vacuum extractors.

The fluid supply system broadly described above may comprise fluid management apparatus (a). The fluid management apparatus may comprise a mass flow controller arranged to receive fluid that has been pressure regulated by the second pressure regulator and to modulate flow rate of fluid flowed to the fluid-utilizing tool. Each of the first fluid pressure regulator and the second fluid pressure regulator can be a fixed set point regulator, or alternatively, each can be a variable set point regulator, with the fluid supply system comprising a monitoring and control assembly operative to dynamically modulate set points of one or both regulators in response to system operating conditions. As a still further alternative, one of the first pressure regulator and second pressure regulator can be a fixed set point regulator and the other regulator can be a variable set point regulator. The flow control component or assembly and the lower voltage segment of the fluid delivery line in such fluid management apparatus (a) may be of any suitable type, and may for example comprise a flow control valve, restrictive flow orifice (RFO), mass flow controller, or other suitable device or assembly adapted to control flow of the fluid in the fluid delivery line.

The fluid supply system broadly described above may comprise fluid management apparatus (b). In such apparatus, the interlock system can be adapted to terminate flow of fluid from the fluid supply source vessel to the fluid-utilizing tool in the event of the electrical disturbance. Additionally, or alternatively, the interlock system can be adapted to terminate power to the fluid-utilizing tool or to one or more parts thereof in the event of such an electrical disturbance. As a further alternative, or additional feature, the interlock system can be of a type that is adapted to transmit a signal indicative of the electrical disturbance to a safety system for the fluid supply system.

The fluid supply apparatus broadly described above may comprise fluid management apparatus (c). In such apparatus, the non-linear fluid delivery line can have any suitable shape, e.g., a wave shape, a “Z” shape, a “S” shape, or a coil shape.

The fluid supply apparatus broadly described above may comprise fluid management apparatus (d). In such apparatus, the reversible sorbent medium may comprise a solid-phase physical adsorbent, e.g., a solid-phase physical adsorbent comprising an adsorbent selected from the group consisting of carbon, silica, molecular sieve zeolite, and macroreticulate polymers. The reversible sorbent medium may be provided in a vessel that is in the fluid delivery line. Multiple volumes of the reversible sorbent medium may be provided in fluid communication with the fluid delivery line along its length. Thus, the reversible sorbent medium may be at a location in the apparatus at the relatively lower voltage, or alternatively at the relatively higher voltage, along the fluid delivery line.

The reversible sorbent medium may comprise two or more adsorbent species, e.g., in a circumstance in which multiple fluids are flowed to the fluid-utilizing tool in mixture with one another, or as provided from separate fluid supply source vessels in which the respective sorbent species are disposed in communication with the separate fluid delivery lines for the respective fluids.

The fluid supply apparatus broadly described above may comprise fluid management apparatus (e). Such fluid management apparatus may comprise a mass flow controller in fluid delivery flow circuitry coupling the fluid supply vessel to the fluid-utilizing tool, and the fluid delivery flow circuitry may comprise a bypass line through the mass flow controller that is controllably openable by the fluid management apparatus to a vent line, pump, or evacuated volume for prevention of pressure surge, and controllably closable by the fluid management apparatus in a manner suppressing the undesired pressure transients.

The fluid supply apparatus broadly described above may comprise fluid management apparatus (f). Such fluid management apparatus may comprise a temperature controller adapted to heat or cool at least part of fluid delivery flow circuitry coupling the fluid supply vessel to the fluid-utilizing tool to control the fluid pressure of the fluid flowed through the flow circuitry in a manner suppressing the transients.

The fluid supply apparatus broadly described above may comprise fluid management apparatus (g). This apparatus may comprise a variable volume surge chamber, e.g., a bellows chamber that is adapted for controllable expansion and contraction to counteract said pressure transients.

The fluid supply apparatus broadly described above may comprise fluid management apparatus (h), namely, an on-board vessel associated with the fluid-utilizing tool and at the relatively higher voltage thereof during operation of the tool, with such on-board vessel being adapted for filling by the fluid supply source vessel during operation or during periods of operations, in which, if adapted to be filled during tool operation, the fluid management apparatus additionally comprises one or more of the foregoing apparatuses (a)-(g).

The disclosure correspondingly contemplates a method of delivering fluid at relatively lower voltage to a fluid-utilizing tool at relatively higher voltage, wherein the fluid passes through a corresponding voltage differential, said method comprising operating a fluid supply system according to any one of above-discussed embodiments. In such method, the fluid may comprise a dopant source gas, and may further comprise a diluent gas and/or a cleaning gas. As mentioned, the delivered fluid may comprise co-flow species that are separately delivered, from separate fluid supply source vessels to the fluid-utilizing tool.

The disclosure further contemplates a method of providing for use in a manufacturing facility comprising a fluid-utilizing tool operated at elevated voltage, a fluid supply system of any of the embodiments disclosed herein.

The disclosure in a further aspect contemplates an ion implantation system comprising a fluid supply system as variously described above in any of the above-discussed embodiments.

The disclosure in a method aspect contemplates a method of operating an ion implantation process system including operation of the fluid supply system as variously described above in any of the above-discussed embodiments.

In specific implementations, the ion implantation system can include a system enclosure, in which is disposed the ion source, magnets, beamline passageway, pumps and other components of the ion implantation system, so that the system includes a unitary housing for at least the major components of the ion implantation system. In such embodiments, the dopant source gas supply vessel is advantageously located outside of such unitary housing, but may alternatively be located inside of such unitary housing. For example, the dopant source gas supply vessel can be located in a below-floor vault in a semiconductor manufacturing facility, and coupled by suitable flow circuitry with the ion implantation system. Alternatively, the dopant source gas supply vessel can be located in a central location on a main floor of a semiconductor manufacturing facility and coupled by suitable flow circuitry with an ion implantation system. In various embodiments, the dopant source gas supply vessel is provided in a gas box at a remote location from the ion implantation system.

As another alternative, the dopant source gas supply vessel may be operatively linked by suitable flow circuitry with multiple respective ion implantation system units in a semiconductor manufacturing facility, so that multiple implant tools are supplied with dopant source gas by a single supply vessel.

The dopant source gas supply vessel that is utilized to provide dopant source gas to one or more ion implantation systems, can be of any suitable type that provides adequate capacity for supplying dopant source gas to the ion implantation system(s), including conventional high pressure gas cylinder supply vessels, pressure-regulated gas storage and dispensing supply vessels, adsorbent-based gas storage and dispensing supply vessels, and combinations of two or more of the foregoing types. The remote dopant source gas supply is desirably constructed and utilized to provide adequate flow and capacity of dopant source gas to the ion implanter for sustained operation, while minimizing interruptions or down time of the implanter tool.

The dopant source gas supply vessel can be of any suitable size and capacity that is appropriate for providing dopant source gas to the local vessel(s) that are coupled in fluid-receiving relationship to the supply vessel. The supply vessel can for example have a volumetric capacity exceeding 40 L, e.g., 50 L, 100 L or more, as may be necessary or desirable in a given semiconductor manufacturing facility in which a dopant source gas supply arrangement of the present disclosure is employed.

The dopant source gas supply vessel in accordance with the present disclosure is located remotely from the ion implanter tool, being physically spatially separated from the tool, and coupled with the tool by dopant source gas by flow circuitry comprising a supply line for flowing dopant source gas from the dopant source gas supply vessel to the ion implanter tool. The separation distance between the dopant source gas supply vessel and the ion implanter tool may be of any suitable dimension, depending on the physical structure and layout of the facility in which the ion implanter tool and the dopant source gas supply vessel are disposed. The dopant gas source supply vessel may be located immediately outside the ion implanter tool housing, or may be meters, tens of meters, or even hundreds of meters away from the ion implanter tool. The dopant source gas supply vessel in such remote installations is at voltage, e.g., ground, that is different from the operating voltage level of the ion implanter tool.

The present disclosure provides for dopant source gas crossing of the voltage gap between the dopant source gas supply vessel and the ion implanter tool in a safe and effective manner.

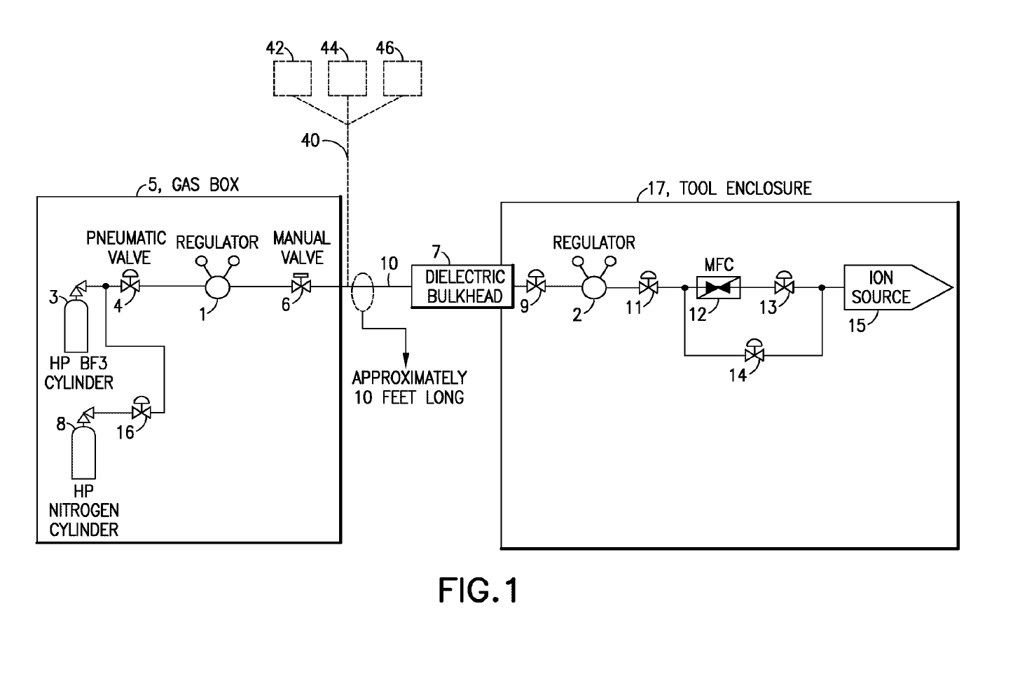

Referring to the figures, FIG. 1 shows an embodiment wherein the dopant source gas supply vessel 3 and optional co-flow gas supply cylinder 8 are provided in a gas box 5. Supply line 10 connects the gas box 5 with the tool enclosure 17 for the ion implanter, and carries the dopant source gas through a high voltage gap and into the ion source 15. Various valves 4, 6 and 16 in the gas box control the flow of the supplied gases from cylinder 3 and cylinder 8. Valves 9, 11, 13 and 14 are shown in the implanter enclosure. Regulator 1 in the gas box and regulator 2 in the ion implanter enclosure are tuned and adjusted depending on the remote delivery distance to allow safe crossing of the dopant source gas through the dielectric bulkhead 7. In various embodiments, the regulators may be set to any suitable pressure levels or pressure set points to cross the high voltage gap. For example, when BF₃ is the dopant supply gas, the regulators may be set to below 760 Torr (101.3 kPa), below 1510 ton (0.201 MPa), below 3020 Torr (0.403 MPa), or other appropriate pressure value, to cross the high voltage gap. A mass flow controller 12 is positioned between regulator 2 and the ion source 15. FIG. 1 illustrates one arrangement of valves and regulators, but other arrangements may be used.

In one particular embodiment, the length of the gas supply line 10 between the gas box and the dielectric bulkhead 7 in the FIG. 1 system is on the order of 3 meters (˜10 feet). In this system, the coordinated tuning of the regulators 1 and 2 establishes their pressure set points so that premature ionization of the gas upstream of the ion source 15 in the ion implanter tool enclosure, as well as arcing and/or electrical discharge, are avoided, thereby achieving a proper balance of factors including pressure of the gas from the high pressure cylinders in supply line 10, the length of the supply line 10, and the voltage condition in the ion implanter tool enclosure relative to the gas box voltage level.

The regulators 1 and 2 may be of fixed (preset) set point type, with the set points of the regulators being fixed at appropriate values for the system characteristics of the specific installation in which the gas delivery system is employed. Alternatively, the regulators may be of variable set point type, in which the respective set points are dynamically modulated in response to system operating conditions, by appropriate monitoring and control apparatus. As a still further alternative, one of the respective gas box and tool enclosure regulators may be a fixed set point regulator, and the other a dynamically adjustable set point regulator.

Thus, the gas box and tool enclosure regulators are coordinated in set points so that the pressure drop across the supply line between such regulators is controlled so that premature ionization, arcing, discharge, or other anomalous behavior is avoided, with the downstream mass flow controller functioning to provide appropriate volumetric flow rate of gas to the ion source for the requisite ionization of gas to be carried out. The mass flow controller 12 is provided with a bypass line containing flow control valve 14. The flow control valve in the feed gas line to the ion source 15 is operable to isolate the mass flow controller and flow feed gas through the bypass line, should operational steps or conditions so require.

The fluid supply source vessels in the gas box 5 can be utilized to supply fluid to multiple fluid-utilizing tools, in which each of the respective fluid-utilizing tools is of a same or alternatively of a different type in relation to the others. As shown in FIG. 1, the supply line 10 may be branched, with a second supply line 40 joined thereto for the purpose of supplying fluid to fluid-utilizing tools 42, 44, and 46.

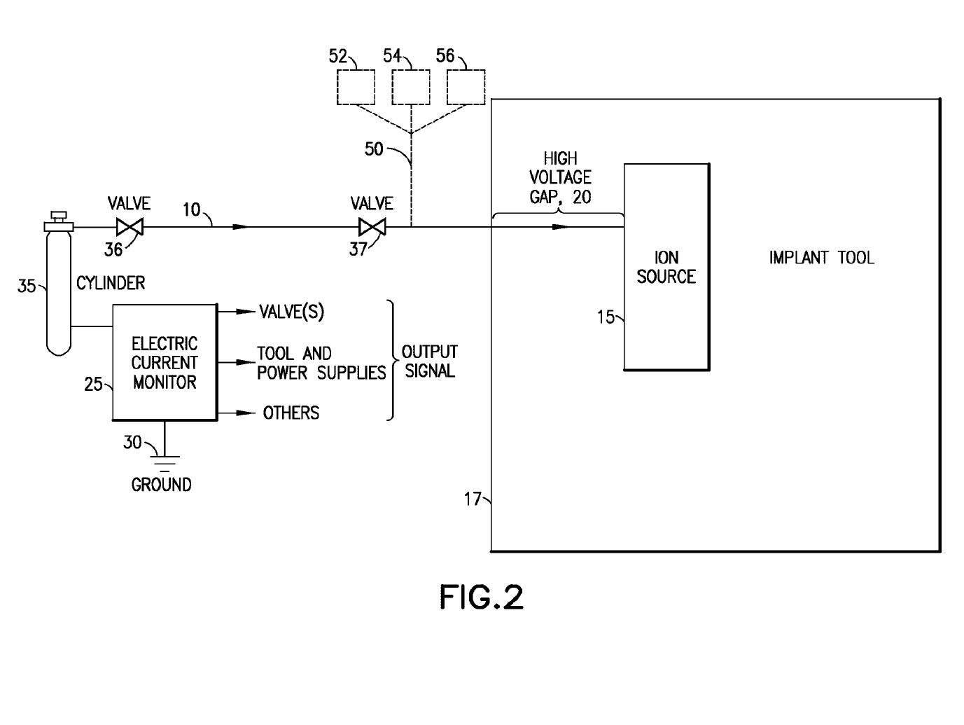

In another embodiment, shown in FIG. 2, electric current monitor 25 is installed between the gas cylinder 35 and the ground 30. In normal operation, the current should be zero or under background noise. The electric current monitor 25 is arranged to detect a current signal. When an event such as arcing or discharging occurs, the current meter will detect the signal and trigger an interlock system to perform one or more actions to prevent damage to the system. One such action may be to shut off the gas supply line valve or valves (for example, valves 36, 37) along supply line 10 which carries the dopant source gas through high voltage gap 20 and into the ion source 15. Alternatively, the interlock system may turn off the power to the implantation unit or system or to one or more parts of the implanter system, such as the high voltage power supply, the gas box power supply, the arc power supply, the filament power supply or others. Another alternative may provide transmission of a monitoring signal from the electric current monitor to other safety systems for response.

It will be recognized that the electric current monitoring system described above in reference to the embodiment shown in FIG. 2 may be utilized in combination with the regulator control system of the embodiment shown in FIG. 1.

In another variation of the fluid supply arrangement shown in FIG. 2, the fluid supply line 10 may be branched, with a second fluid supply line 50 being provided to supply fluid from the gas cylinder 35 to fluid-utilizing tools 52, 54, and 56.

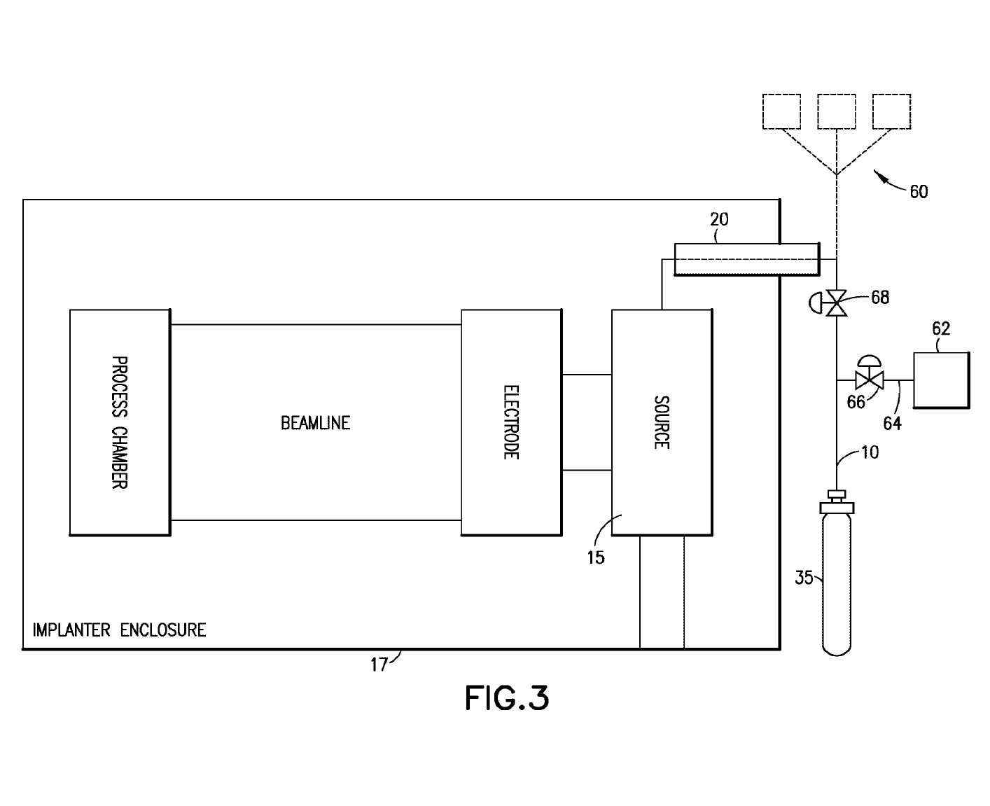

In another embodiment (FIG. 3), the length of the supply line is extended to increase the gas breakdown voltage with lower gas pressure. The supply line 10 across the high voltage gap 20 has an extended length. Such length may be obtained by using a supply line in, for example, a wave shape: [symbol] ; a “Z” or S″ shape: [symbol] ; or a coil shape: [symbol] .

Other shapes may be suitable to increase or extend the total length of the supply line. By providing a longer supply line from the dopant source gas supply vessel 35 to the ion source 15, the gap path for the high voltage gap section will be extended, thereby eliminating arcing or breakdown through the gas, consistent with Paschen's law:

$$V = \frac{ apd}{ln ( pd ) + b}$$

wherein: V is the breakdown voltage in volts; p is the pressure in atmospheres or bar; d is the gap distance in meters, and a and b are constants whose values depend on the composition of the gas.

The supply line thus can be made sufficiently long to allow pressure in the high voltage gap region to be low enough to enable the gas to be delivered from the remote dopant source gas supply vessel crossing the high voltage gap without arcing or breakdown.

The supply line conveying fluid across the voltage differential may also be constructed and arranged to reduce the incidence of arcing or breakdown along the supplied fluid flow path in proximity to the voltage differential, in various manners. For example, the supply line may comprise plastic lines that are doubly or otherwise multiply contained, such as in an array of concentric tubes. The supplied gas may comprise a high dielectric constant gas component to reduce the incidence of arcing or other anomalous electrical behavior, or the high dielectric constant gas may be used as a shrouding fluid for the supplied fluid to be utilized in the downstream tool. The high voltage gap may also be constructed such that it can be selectively isolated or cyclically purged to enable maintenance to be carried out.

In the FIG. 3 embodiment, a surge chamber 62 may be provided, being supplied with fluid from the gas supply vessel 35 by branch line 64 joined to supply line 10. Branch line 64 contains flow control valve 66 therein, so that the surge chamber 62, once filled with fluid from the gas supply vessel 35, can be isolated if desired, by closing the valve 66, to provide a back-up supply of fluid during change out of the gas supply vessel 35 when it is depleted and being replaced by a fresh gas supply vessel, or otherwise when the remote fluid supply source requires maintenance Alternatively, the valve 66 may be retained in an open position, to allow the surge chamber 62 to buffer the flow of fluid in supply line 10, to thereby minimize pressure fluctuations in the flow of fluid to the ion source 15. The supply line 10 may also contain a flow control valve 68 therein, to modulate flow of fluid through line 10. The respective valves 66 and 68 may be operably linked to valve controllers that are in turn coupled in signal transmission relationship to a monitoring and control processor that also receives signal inputs from various system sensors or monitors, so that the valves 66 and 68 are automatically operated in response to process system conditions.

As a further variation, the supply line 10 may, in addition to supplying fluid to the ion source 15 in implanter enclosure 17, feed fluid to additional tools, shown in dashed line representation as tool array 60.

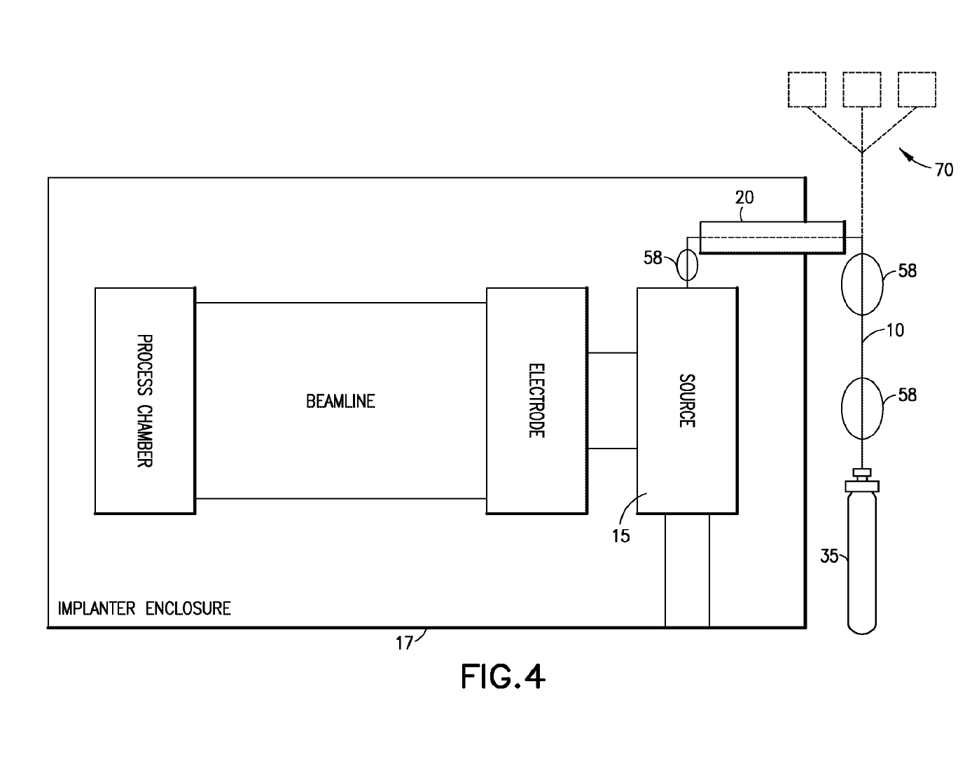

In another embodiment, a buffer station may be provided along the supply line between the dopant source gas supply vessel and the ion source in the ion implantation unit (supply line 10, carrying the dopant source gas through high voltage gap 20 and into the ion source 15). As shown in FIG. 4, buffer stations or containers 58 may be located anywhere along supply line 10 inside the implanter enclosure or may be located along the supply line 10 outside the implanter unit. There may be one buffer station, or multiple buffers stations as shown in FIG. 4. The buffer stations may contain any material suitable for reversibly adsorbing gases. For example, the buffer stations may contain carbon material. The gas may be drawn from or through the buffer stations. The buffer stations may be charged with gas from the main gas supply during operation or during idle time. The buffer stations may be used to maintain stable pressure or flow to the implanter unit, particularly when there is pressure variation during flow of dopant source gas from the dopant source gas supply vessel to the ion implanter unit or system.

The buffers thus can be arranged so that adsorbed dopant source gas on a buffer adsorbent medium is desorbed when pressure declines, in an amount to compensate for the pressure diminution in the line containing the buffers, so that pressure increases in the line. Conversely, if pressure in the line containing the buffer increases, the dopant source gas in the line will adsorb on the sorbent medium in an amount to serving to reduce the line pressure, thereby relieving the overpressure condition.

The buffers will correspondingly be provided with sorbent medium that is reversibly sorptive for the gas(es) being flowed to the implanter. If a gas mixture is being flowed to the implanter, the buffer may suitably contain a sorbent medium that has sorptive affinity for the separate gases of the mixture, so that the respective gases are adsorbed and desorbed concurrently to maintain the pressure condition and the gas composition within allowable limits. Accordingly, the sorptive medium in the buffer may comprise a mixture of sorbent materials each of which has a sorptive affinity for a different gas in the gas mixture being flowed to the ion implanter tool. If gases are being flowed separately in respective supply lines, e.g., a first supply line for a dopant gas and a second supply line for a carrier gas, with each supply line passing through a high voltage gap, buffers may be provided on each of the respective gas supply lines, with appropriate sorbent medium in each of the respective buffers.

The buffers may simply be provided as in-line vessels containing appropriate sorbent medium. The sorbent medium can be of any suitable type, and buffers can for example contain sorbent materials such as carbon, silica, molecular sieve zeolite, etc.

As a further variation of the FIG. 4 system, the supply line 10 may, in addition to supplying fluid to the ion source 15 in implanter enclosure 17, feed fluid to additional tools, shown in dashed line representation as tool array 70.

In remote delivery applications in which gas is being delivered to an ion implantation tool or system from a centralized location, a steady, consistent supply of gas to the implanter is desired. In installations in which a single remote dopant source gas supply vessel delivers gas to more than one implanter tool, an interruption of gas flow from the central dopant source gas supply vessel would render multiple implanters inoperable. In order to avoid such circumstance, the dopant source gas supply vessel may be coupled with a smaller supply vessel that is on-board the implanter. The on-board supply vessel would provide a buffer volume of gas that would be used to sustain processing when the centralized dopant source gas supply is interrupted. The on-board supply vessel may be filled with adsorbent, such as carbon, silica, molecular sieve zeolite, etc., and sized to accommodate sufficient inventory of gas for the implanter to continue to run while the problem at the remote dopant source gas supply vessel is diagnosed and remedied. Such on-board supply vessel may be connected to a control system and arranged such that the gas supply is switched from the remote dopant source gas supply vessel to the on-board gas supply vessel upon detection of a failure in the gas flow from the dopant source gas supply vessel or other event affecting the remote supply vessel.

The dopant source gas supply system for the ion implantation system may include a number of monitoring systems. As shown in and described with reference to FIG. 2, an electric current monitor may be employed in the system to detect electrical events. In other embodiments, a control system may be employed to monitor and control the supply pressure and/or the demand flow rates of the gas flowed to the ion implanter or implanters connected to the dopant source gas supply vessel. Control systems may be provided to monitor and control the supply pressure and/or the flow rates in a gas distribution manifold coupled to supply lines to the various implanters, in order to prevent pressure transients that could adversely affect the performance of the individual ion implanters. To account for a reduction or change in flow that may be caused by a tool stopping operation or changing its process, a bypass line through a mass flow controller may be opened to a vent line, pump, or evacuated volume to maintain the total flow rate of the delivery system at suitable level for preventing a pressure surge. The flow in the bypass line may then be slowly ramped down to zero flow in a manner that avoids a pressure transient. Alternatives to this method may be to implement temperature control to rapidly heat or cool a portion of the distribution manifold thus controlling the gas pressure. In a further embodiment, a large dedicated volume may be provided in the distribution system to minimize the amplitude of any pressure transients. This volume may, for example, incorporate a bellows into its construction such that the volume of the system could be varied to counteract a pressure transient.

When an on-board supply vessel is used, such vessel may be refilled in any appropriate manner. In order to reduce the refill time, rapid fill arrangements may be employed, such as high-conductance fill ports on the on-board vessel, or fill tubes extending into the interior volume of the on-board vessel, having a coiled, looped, serpentine, “S”-shaped, or other non-linear conformation, and provided with gas-discharge openings along their length, allowing gas to flow into numerous portions of the interior volume (e.g., into numerous portions of the sorbent, when the on-board vessel contains a sorbent medium for the gas).

Although sorbent media such as solid-phase physical adsorbents have been described as a reversible storage medium for gas in supply and on-board vessels, the disclosure also contemplates other reversible storage media, such as ionic liquid storage media.

The fluid supply systems of the present disclosure can be employed to provide a stable supply of fluid to multiple tools in a fluid-utilization facility, e.g., multiple ion implantation tools in a semiconductor manufacturing facility, or to multiple tools in facilities for producing flat panel displays or photovoltaic cells.

When a remote fluid source of the present disclosure is used to supply multiple fluid-utilizing tools across respective voltage differentials, changes in flow rate of one or more of the multiple tools does not negatively affect the flow stability of the remaining tools. Then, having an additional regulator in each tool enables “stepping down” of the pressure to a desired pressure level, e.g., subatmospheric pressure in the case of ion implantation tools, as generally desired for safety reasons, and to avoid outboard leaks that may cause corrosion of the implanter components. Such additional regulators within the implanters also serve to dampen any upstream pressure disturbances.

For example, in an arrangement including multiple fluid supply lines from a gas box containing a single regulator, the pressure of the fluid flowed to all of the respective ones of the multiple tools can be controlled to a predetermined level, to minimize the incidence of arcing, discharge, or premature ionization of the fluid as a result of the fluid crossing a voltage differential in passage to each of the respective tools.

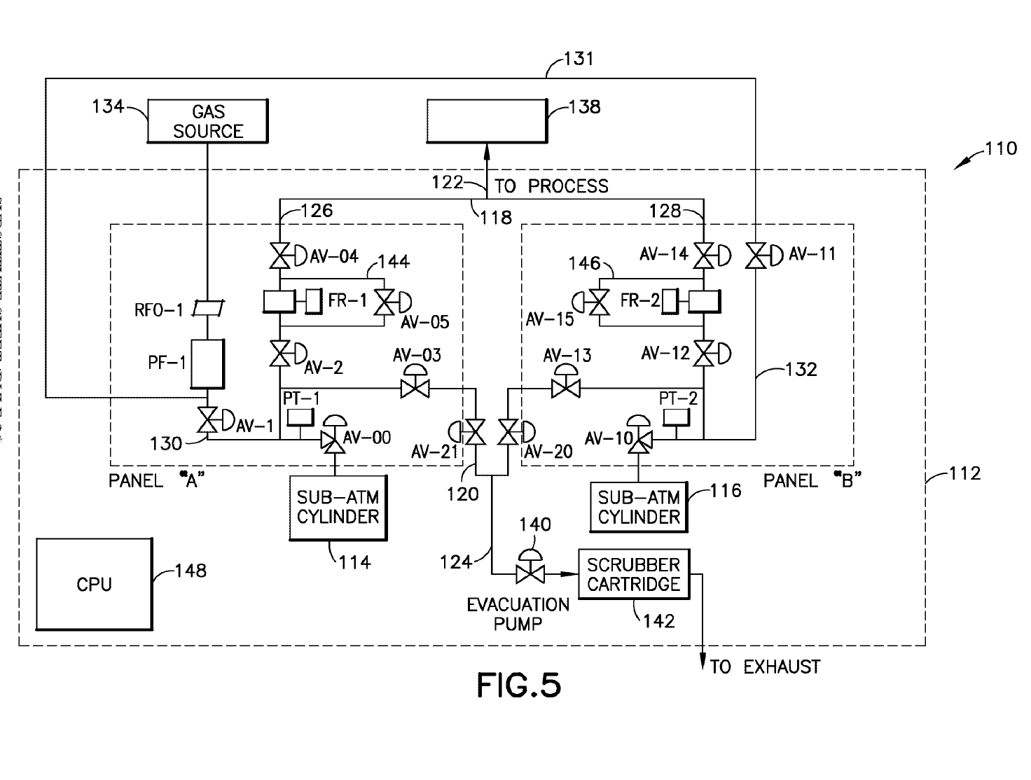

FIG. 5 is a schematic representation of an auto-switching sub-atmospheric pressure gas delivery assembly according to one embodiment of the present disclosure.

As illustrated in FIG. 5, the sub-atmospheric pressure gas delivery assembly 110 comprises a gas cabinet assembly 112 schematically depicted in dashed line representation, and including two individual gas cabinet enclosures that are connected to one another, with each such enclosure housing a respective one of the two gas panels. The gas cabinet for each panel may comprise a unitary enclosure and be equipped with access doors, gas supply vessel securement members, etc., as is known in the art.

The gas delivery assembly 110 as illustrated includes respective gas panel assemblies, denoted “PANEL A” and “PANEL B” in FIG. 5, which are generally symmetrical to one another, comprising piping, valving, flow control and processing monitoring means, for gas delivery, purge and evacuation modes of operation. As described hereinabove, PANEL A is in a first gas cabinet and PANEL B is in a second gas cabinet, with each of the gas cabinets being connected to one another. Each of the gas panels may be integrated with (interactively coupled to) a single central processing unit (CPU) 148.

The respective gas panel assemblies are coupled with product gas discharge manifold line 118, to which is joined the product discharge flow line 122. The product discharge flow line 122 is in turn connected to the gas-consuming facility 138, which may comprise for example a semiconductor manufacturing tool or other process unit.

In the gas delivery assembly 110, the automatic valves are denoted by the prefix “AV-” followed by a number for the specific valve unit. Restricted flow orifice elements are employed in the system and are denoted by the prefix “RFO-” followed by the number of the specific restricted flow orifice unit. Particle filters are denoted by the prefix “PF-” followed by the number of the specific particle filter unit. Pressure transducer elements are denoted by the prefix “PT-” followed by the number of the specific pressure transducer unit. Pressure-controlled flow regulating devices are denoted by the prefix “FR-” followed by the number of the specific pressure-controlled flow-regulating device.

As illustrated, PANEL A includes a purge line 130 coupled with the purge gas source 134. The purge gas source 134 may comprise a cylinder or other supply container, or a “house” bulk purge source of purge gas for selective flow of purge gas through the purge line 130. The purge line 130 contains automatic valve AV-1, restricted flow orifice RFO-1, and an optional particle filter PF-1. The PANEL A main gas flow line 126 interconnects the product gas discharge manifold line 118 with the fluid supply source vessel 114, which may for example comprise a sub-atmospheric pressure fluid cylinder, or alternatively a superatmospheric pressure fluid cylinder, e.g., containing one or more pressure regulators, as well as the purge gas manifold line 120. The purge line 130 is coupled via line 131 to purge line 132 of PANEL B, so that purge gas source 134 serves both PANEL A and PANEL B.

In the fluid dispensing mode, gas is flowed from the fluid supply source vessel 114 through the main gas flow line 126, the product gas discharge manifold line 118 and the product discharge flow line 122 to the gas-consuming facility 138, which may comprise a CVD tool, e.g., for the deposition and incorporation of arsenic and phosphorus atoms in thin film substrates used in the manufacture of microelectronic device structures.

The main gas flow line 126 is coupled to the fluid supply source vessel 114 by a valve head assembly including a valve AV-00. The main gas flow line 126 contains a pressure transducer PT-1, automatic valve AV-2, pressure-controlled flow regulating device FR-1, and automatic valve AV-04, and such line 126 is coupled with optional by-pass flow control loop 144 containing automatic valve AV-05.

PANEL B is correspondingly constructed to PANEL A. PANEL B comprises a purge line 132 coupled with the purge gas source 134 via line 131 joined to purge line 130, as shown. The purge gas source 134 as mentioned may comprise a cylinder or other supply container having a suitable purge gas therein. The purge gas source 134 supplies purge gas that is selectively flowable through the purge line 132. Alternatively, the purge gas source 134 instead of being a single source from which purge gas is selectively dispensable to each of the purge lines 130 and 132 in sequence, may otherwise comprise separate purge gas sources associated directly with each of the respective PANELS A and B. With such separate purge gas sources, the purge gas line 132 in PANEL B would be configured analogously to purge gas line 130 in PANEL A, and may include a restricted flow orifice and optional particle filter as shown for the purge gas line 130 in PANEL A.

The purge line 132 contains automatic valve AV-11. The PANEL B main gas flow line 128 interconnects the product gas discharge manifold line 118 with the sub-atmospheric pressure gas supply vessel 116, as well as the purge gas manifold line 120.

The main gas flow line 128 is coupled to the fluid supply source vessel 116 by a valve head assembly including a valve AV-10. The main gas flow line 128 contains a pressure transducer PT-2, automatic valve AV-12, pressure-controlled flow regulating device FR-2, and automatic valve AV-14. Line 128 also is provided with optional by-pass flow control loop 146 containing automatic valve AV-15.

Purge gas manifold line 120 interconnects the main gas flow lines 126 and 128 as shown. Automatic valves AV-03 and AV-13 are provided in the PANEL A and PANEL B segments of the purge gas manifold line 120, respectively. The purge gas manifold line 120 in turn is joined to purge gas discharge line 124 containing evacuation pump 140 and optional scrubber cartridge 142. The scrubber cartridge 142 may comprise an in-line canister containing a suitable chemisorbent or scavenger material which effects removal from the purge gas of undesired gas component(s) prior to exhaust of the purge gas from the gas cabinet 112. The exhausted purge gas may be sent to exhaust from the system, recycled in the system, and/or treated in whole or part for abatement of the contaminants therein.

In this respect, the integral scrubbing cartridge 142 in the purge gas discharge line 124 functions to capture residual emissions from the evacuation vacuum pump 140.

The evacuation pump 140 may suitably comprise a vacuum pump although other devices may be employed, e.g., eductors, ejectors, cryopumps, fans, blowers, etc. The isolation valves, automatic valves AV-03 and AV-13, isolate the vacuum drive component, evacuation pump 140, from the panels' evacuation circuitry. The individual panels allow for local pump purging, local evacuation, and isolated cylinder changing.

The process delivery lines comprise indicating pressure transducers (PT-1 in PANEL A; PT-2 in PANEL B) at each cylinder (supply vessel 114 for PANEL A; supply vessel 116 for PANEL B), high flow, i.e., high CV, valves (AV-00 for supply vessel 114; AV-10 for supply vessel 116), and downstream pressure control devices (AV-2, FR-1 and AV-4 in PANEL A; AV-12, FR-2 and AV-14 in PANEL B), including optional bypass loops (loop 144 containing AV-05 in PANEL A; loop 146 containing AV-15 in PANEL B).

The flow control devices FR-1 and FR-2 are used to ensure a smooth transition during switching from empty to full sub-atmospheric pressure cylinders in the respective PANELS A and B. That is, the flow control devices FR-1 and FR-2 prevent the pressure in the full cylinder from spiking the downstream delivery system and, thus, the process tool. The flow control devices FR-1 and FR-2 may each comprise a commercially available device such as the MKS 640 Series pressure controller (available from MKS Instruments, Inc.) or a pressure control assembly comprising a combination of a downstream pressure transducer, a variable setting (proportioning) control valve, and a PID controller, which may be included in the system's overall process control system. Preferred flow control devices include the Model SR-3 and Model SR-4 subatmospheric pressure regulators commercially available from Integrated Flow Systems, Inc. (Santa Cruz, Calif.), which may be selectively set at pressure settings, e.g., at a pressure in the range of from about 20 to about 50 Torr.

The gas delivery assembly 110 may also comprise in the gas cabinet a central processing unit (CPU) 48, which may be operatively linked to the valves, controllers and actuators in the system, for control of such system components according to a cycle time control program or in other automatically controlled manner. The CPU may comprise a programmable computer, microprocessor, or other microelectronic unit for such purpose. Preferably, the CPU comprises a programmable logic controller (PLC).

The CPU alternatively may be situated outside of the cabinet 112 and operatively linked to the valves, controllers and actuators of the system in a suitable fashion, e.g., by signal transmission wires, wireless (e.g., infrared) link, etc.

A typical auto-switch operation of the gas delivery assembly 110 of FIG. 1 is now described, wherein PANEL A is in an “Operating” mode and PANEL B is in a “Stand-By” mode, and cylinders 114 and 116 are connected to the respective PANEL A and PANEL B assemblies.

In PANEL A, gas from cylinder 114 is flowed through the open valve AV-00 in main gas flow line 126, with valves AV-2 and AV-04 also being open, so that the supplied gas passes into product gas discharge manifold line 118 and is discharged from the gas cabinet 112 into product discharge flow line 122 for flow to the gas-consuming facility 138.

During such dispensing operation in PANEL A, the valves AV-1 and AV-3 are closed. The pressure transducer PT-1 monitors the pressure of the dispensed gas from sub-atmospheric pressure supply cylinder 14, and the monitored pressure is inputted to the CPU 148 for control purposes, while the pressure-controlled flow regulating device FR-1 controls the flow of the dispensed gas to the gas-consuming facility 138 in accordance with the requirements of the facility.

When cylinder 114 connected to PANEL A approaches an empty condition, PANEL B is automatically readied under the control of the CPU 148 for switching. The empty and near-empty states of the cylinders may be defined by the end-user by programming the CPU, or the respective empty and near-empty set points may be pre-set in the CPU as furnished to the end-user.

Readying PANEL B for switching entails performing purge and evacuation cycles and charging PANEL B with gas. During these process steps, the pressure-controlled flow regulating device FR-2 will be fully closed using a direct digital signal from the CPU 148, e.g., by a system programmable logic controller (PLC) of such CPU.

In the purging of PANEL B, purge gas from the purge gas source 134 is flowed from line 131 into purge line 132 to the purge gas manifold line 120 and exhausted from the gas cabinet 112 in purge gas discharge line 124 under the action of the evacuation pump 140. During the purge step, the valves AV-11, AV-13 and AV-20 are open, and valves AV-10, AV-12 and AV-14 are closed. The purge gas from source 134 is flowed in line 130 through the restricted flow orifice RFO-1 to prevent the occurrence of pressure surges and regulate the pressure drop in the purge flow circuit. Alternatively, the respective valves AV-11 and AV-13 can be toggle-sequenced, to selectively pressurize the corresponding segments of line 132 in PANEL B (or, correspondingly, valves AV-1 and AV-3 in the analogous sequence in PANEL A), followed by vacuum extraction of the purge gas from the line, in the purge operation.

After the purging step, the valve AV-11 is closed, and the purge flow circuit comprising purge gas discharge line 124 and purge gas manifold line 120 is evacuated under the continuing action of the evacuation pump 140. After evacuation has been completed, the valves AV-13 and AV-20 are closed, and the gas dispensing circuitry of PANEL B (comprising main gas flow line 128) is refilled with product gas and brought to active dispensing condition.

To effect the refill of the gas dispensing circuitry of PANEL B for active dispensing, valve AV-14 is opened in main gas flow line 128 and the pressure transducer of the pressure-controlled flow regulating device FR-2 of PANEL B is exposed to the delivery line pressure, which is that of the vessel 114 that is connected to PANEL A and still in the active dispensing mode.

When the pressure in the product discharge flow line 122 reaches the lower or “empty” setpoint, as sensed by the pressure transducer of the pressure-controlled flow regulating device FR-2 of PANEL B, then valves AV-10 and AV-12 of PANEL B open. At this point, the digital signal that closes the pressure-controlled flow regulating device FR-2 control valve is terminated, and the pressure-controlled flow regulating device FR-2 begins operating to keep the pressure of PANEL B within 10 Torr above that of PANEL A. Simultaneously, valves AV-2 and AV-4 in PANEL A close and a pump/purge cycle begins to remove residual gas from PANEL A.

The pressure-controlled flow regulating device FR-2 slowly opens its proportioning control valve to a “fully open” state in a manner such that the rate of rise of process gas in the delivery line is less than 20 Torr/minute, which is the rate that most mass flow controllers (MFCs) can withstand without compromising flow stability.

Once the delivery line pressure at the pressure-controlled flow regulating device FR-2 equals that of the vessel 116 as determined by pressure transducer PT-2, the pressure-controlled flow regulating device FR-2 can be fully opened to provide unrestricted flow.

At this point, PANEL A is “off-line” (inactive with respect to dispensing of product gas) and may undergo the purging/evacuation and fill sequence described hereinabove for PANEL B. PANEL B during such purging/evacuation and fill sequence of PANEL A continues to dispense product gas.

With valve AV-00 in PANEL A being closed during the purging/evacuation and fill sequence in such panel, the “used” vessel 114 in PANEL A can be changed out—i.e., removed and replaced by a fresh (full) vessel, for subsequent renewed operation of PANEL A as the active gas dispensing panel of the gas delivery system when the vessel in PANEL B is exhausted, and the aforementioned auto-switching procedure is carried out.

It is preferred to avoid the use of the pressure-controlled flow regulating device FR-2 as a fixed regulator, in order to provide the end-user with the capability to employ a mass flow controller (MFC) in the gas-consuming facility 138 as a measure of the remaining product gas in the vessel that is supplying product gas to the facility. The end-user may for example record the MFC's valve voltage reading and use such valve voltage reading as the measure of the approach to the vessel's “empty” state. The MFC valve voltage increases proportionally with decreasing pressure in the sub-atmospheric pressure gas supply vessel, and it is preferred from an MFC accuracy standpoint to operate at higher base pressures, e.g., >20 Torr.

Although the FIG. 5 embodiment has been illustratively shown and described with reference to a gas delivery assembly utilizing two gas panels (PANEL A and PANEL B), it will be appreciated that the disclosure is not limited in such respect, and that more than two gas panels may be employed in a given end use application, wherein each panel undergoes the cycle steps just described (active gas dispensing, purge, evacuation and fill transition to dispensing condition), in a sequence that is automatically switched with respect to the constituent gas panels.

It will therefore be seen that the auto-switching gas delivery assembly permits continuous dispensing operation to take place, with one of the multiple gas panels being an active dispensing panel, and the other(s) being purged, evacuated and fill transitioned in sequence.

This auto-switching assembly prevents large pressure waves from being propagated through the delivery line as a result of auto-switching between empty and full cylinders. Such auto-switching system ensures continuous delivery of gas in applications in which fungible gas cylinders may be stockpiled to provide a cylinder inventory from which a fresh cylinder may be readily installed during the change-out for a given gas panel.

Additionally, the operation of the gas delivery assembly prevents the occurrence of pressure spikes during the auto-switch operation and thereby serves to minimize particle shedding from individual system components. As a result, the purity of the gas dispensed by the gas delivery assembly is maintained at a high level, as is necessary in gas-consuming operations such as semiconductor manufacturing, in which deviations from the set point purity level may yield a semiconductor product that is defective or even useless for its intended purpose.

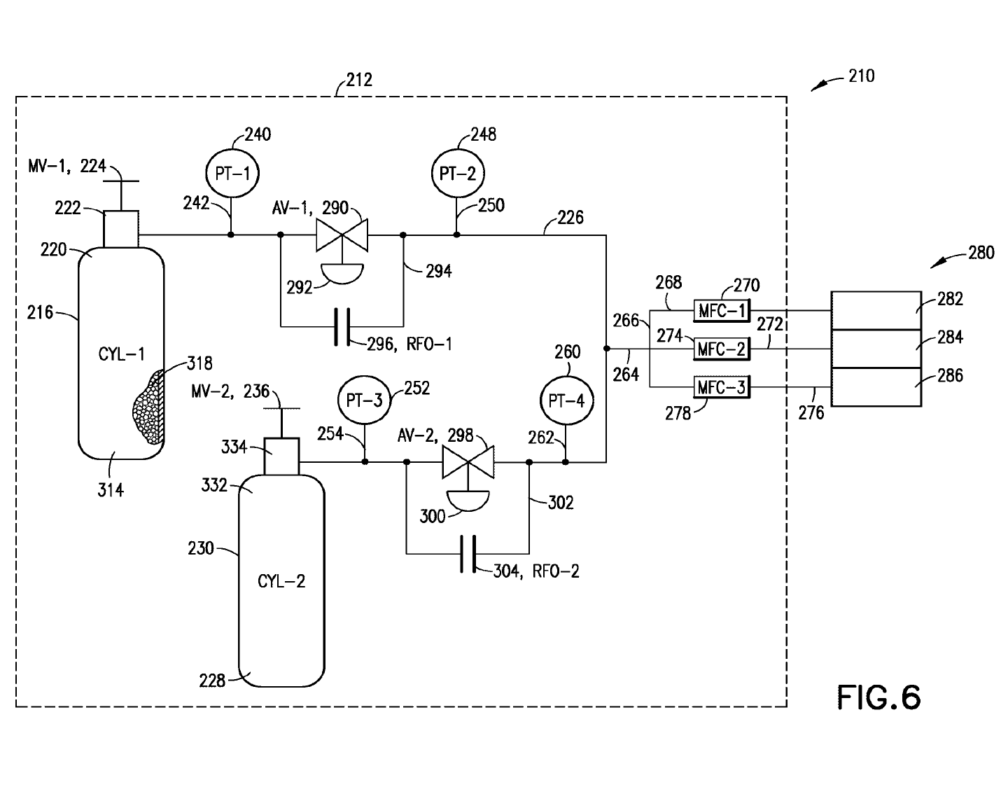

FIG. 6 is a schematic representation of an auto-switching assembly 210 according to another embodiment of the present disclosure. In the FIG. 6 embodiment, a gas cabinet 212 (schematically represented by the correspondingly numbered dashed line in the drawing) contains two gas supply vessels 314 and 228 manifolded to one another by the gas cabinet manifold line 226.

The gas supply vessel 314 as shown includes a casing 216 at the upper neck region 220 of which is provided a valve head 222 with associated valve 224 (MV-1). The valve 224 may be a manually operated (e.g., hand wheel-type) valve or it may alternatively be an automatically operated valve having an associated valve actuator and controller (not shown).

The gas supply vessel 314 contains a bed of sorbent 318 having sorptive affinity for a gas that is physically adsorbed thereon. The sorbent may be a material such as a zeolite, silica, alumina, carbon (e.g., bead activated carbon), or the like, sorptively loaded with a gas. The gas may be a gas dispensed for semiconductor manufacturing, such as hydride gases, halide gases, and gaseous organometallic compounds and complexes. Specific gas species may include, e.g., arsine, phosphine, boron trifluoride, boron trichloride, diborane, silane, halosilanes, etc.

The second sub-atmospheric pressure gas supply vessel 228 is analogously constructed, including a casing 230 with an upper neck region 332 to which a valve head 334 is secured, featuring a valve 236 (MV-2).

The gas supply vessels 314 and 228 are each joined, by suitable coupling or fitting means (not shown) to the manifold line 226. The manifold assembly includes pressure tap 240 (PT-1) joined by pressure tap line 242 to the manifold line 226. Downstream is a second pressure tap 248 (PT-2) connected to the manifold line 226 by pressure tap line 250.

The portion of the manifold line 226 associated with the second gas supply vessel 228 includes the pressure tap 252 (PT-3) connected to the manifold line by pressure tap line 254 and pressure tap 260 (PT-4) connected to the manifold line by pressure tap line 262.

The manifold line 226 is connected to discharge line 264, which in turn is connected to a discharge manifold line 266. The discharge manifold line 266 is coupled with three gas feed lines 268, 272 and 276 containing mass flow controllers 270 (MFC-1), 274 (MFC-2) and 278 (MFC-3), respectively, as shown.

The three gas feed lines 268, 272 and 276 are coupled in gas supply relationship to sections 282, 284 and 286 of the semiconductor manufacturing facility 280, respectively. The respective sections 282, 284 and 286 of the semiconductor manufacturing facility schematically represent different tools or use locations in the semiconductor manufacturing facility, it being understood that the arrangement shown is for illustrative purposes only, and that in general, any number of suitable gas feed lines may be connected to the gas cabinet 212.

In place of the specifically described semiconductor manufacturing facility, any other gas-consuming process facility may be utilized as the user of gas supplied by the gas supply assembly.

The FIG. 6 assembly may be integrated with the fluid supply system of the disclosure in any suitable manner. The FIG. 6 assembly includes flow control valves 290 and 298, each of which is associated with a bypass loop containing a restricted flow orifice. Thus, the flow control valve 290 (AV-1) is disposed in manifold line 226 with the manifold line upstream and downstream of the valve being joined to bypass loop 294 containing restricted flow orifice 296 (RFO-1). The valve actuator 292 of valve 290 (AV-1) in turn is coupled to a CPU of suitable type, or otherwise controllably arranged in the manifold for automatic switching thereof.

Correspondingly, the flow control valve 298 (AV-2) is disposed in manifold line 226 with the manifold line upstream and downstream of the valve being joined to bypass loop 302 containing restricted flow orifice 304 (RFO-2). The valve actuator 300 of valve 298 (AV-2) is likewise coupled to a CPU, or otherwise controllably arranged in the manifold.

The dimensions of the respective gas flow orifices may be selectively determined without undue effort, to achieve a desired flow conductance for the gas flows through the restricted flow orifices 296 (RFO-1) and 304 (RFO-2) in the parallel flow paths (bypass flow loops 294 and 302) associated with the respective valves 290 (AV-1) and 298 (AV-2). The size of the orifice is most strongly determined by the gas characteristics, but may for example be in the range of from about 0.004 to about 0.020 inches in diameter.

In operation of the FIG. 6 system, assuming that gas supply vessel 314 has been onstream in active gas supplying operation, with the valve 224 (MV-1) open, so that gas flows through the manifold line 226 to the semiconductor manufacturing facility 280, the pressure of the gas dispensed from vessel 314 declines as the vessel is depleted of gas in ongoing operation, finally reaching a changeover pressure level, e.g., on the order of 20 Torr. Meanwhile, the fresh vessel 228, at a pressure on the order of 650 Torr, is coupled in the gas supply system to the manifold line 226, with the valve 236 (MV-2) closed.

At the moment of changeover, the depleted vessel 314 is shut off by closure of the valve 224 (MV-1), and the valve 236 (MV-2) on the fresh vessel 228 is opened.

The opening/closing of the valves 224 (MV-1) and 236 (MV-2) may be carried out manually according to a operating cycle of predetermined time character, or alternatively the valves 224 (MV-1) and 236 (MV-2) may be controllably linked to a CPU by suitable actuator and signal transmission means (not shown) so that the valves on the valve heads of the respective vessels can be automatically operated in accordance with a cycle time program stored in or otherwise provided by the CPU.

As a result of the change in the status of valves 224 (MV-1) and 236 (MV-2), and the action of the bypass loops 294, 302, restricted flow orifices 296, 304, and valves 290 and 298, gas will flow from vessel 228 through the valve head passage of valve head 334 into the manifold line 226, thereby gradually increasing the pressure of the gas supply manifold measured at pressure taps 252 (PT-3) and 260 (PT-4)

The rate of increase in pressure is controlled, so that the pressure rise does not affect the operability of the mass flow controllers 270 (MFC-1), 274 (MFC-2) and 278 (MFC-3), and steady-state, uninterrupted flow of the dispensed gas is achieved over the course of the auto-switching operation.

The manifold of the FIG. 6 system is valvably (by operation of valve elements) arranged for sequential switchover of the gas supply vessels, in series, by appropriate control of the various manifold and vessel valves so that dispensing pressure is maintained in the manifold appropriate to prevent destabilizing perturbations of the mass flow controllers from occurring.

In the FIG. 6 system, additional flexibility may be provided in the gas supply system by providing the restricted flow orifice elements as variable restriction elements, so that the flow conductance of the bypass loop flow can be selectively modified during use of the system, to accommodate different sub-atmospheric pressure levels, downstream gas-consuming operations, and types of gases.

Furthermore, the auto-switching assembly may be variously configured to provide integration of the monitoring elements and instrumentation in the fluid supply system, to provide feedback adjustment capability for set point or optimized operation of the system. For example, the pressure taps (PT-1, PT-2, PT-3 and PT-4) may be controllingly linked to a CPU and employed to vary the cycle time and actuation of the various system valves. The mass flow controllers may independently or interdependently arranged to be adjusted as to their respective set points. A CPU cycle may be programmatically varied with temperature compensation via thermocouple sensing at respective locations in the system and associated temperature adjustment feedback assemblies. Many other modifications and variations are possible.

It will be recognized that the fluid supply systems of the present disclosure can be implemented with varied types and arrangements of auto-switching assemblies, to enable continuous flow provision of fluid to the fluid-utilizing process and apparatus.

Thus, the fluid supply system of the disclosure can comprise multiple fluid supply source vessels, and the system can further comprise an auto-switching assembly operatively coupled with the multiple fluid supply source vessels for maintaining continuous flow of fluid by switching from a depleted vessel to a fresh fluid-containing one of the multiple fluid supply source vessels in the fluid dispensing operation.

It will correspondingly be appreciated that the present disclosure provides a variety of approaches and techniques for effecting remote delivery of gas to a tool operated at higher voltage than is present at the remote delivery gas source, and various combinations of such approaches and techniques are contemplated by the present disclosure.

The advantages and features of the disclosure are further illustrated with reference to the following example, which is not to be construed as in any way limiting the scope of the disclosure but rather as illustrative of one embodiment of the disclosure in a specific application thereof.

### EXAMPLE

A system of the type shown schematically in FIG. 1 was evaluated with a pressure-regulated dopant source gas supply vessel (VAC® gas supply package, commercially available from ATMI, Inc., Danbury, Conn., USA) containing B₂F₄. The system was tested for pressure drop with high voltage off, and was evaluated to determine its capability to deliver up to 20 sccm of flow from the dopant source gas supply vessel in the gas box as shown in FIG. 1. The results are shown in Table 1:

TABLE 1

| | | Regulator 1 | Regulator 2 | |
|---|---|---|---|---|
| Flow Rate Set | Actual B₂F₄ | Pressure | Pressure | Source Ion |
| Point (sccm) | Flow Rate | (torr) | (torr) | Gauge (Pa) |
| 0 | 0 | | | 1.90 * 10⁻⁴ |
| 8.3 | 5 | 453 | 453 | 1.70 * 10⁻³ |
| 16.5 | 10 | 408 | 438 | 3.60 * 10⁻³ |
| 24.7 | 15 | 393 | 400 | 5.65 * 10⁻³ |
| 33 | 20 | 385 | 393 | 7.80 * 10⁻³ |
| 36 | 21.8 | 385 | 393 | 8.50 * 10⁻³ |

The results evidenced very little pressure drop between the gas box 5 and the mass flow controller 12. Thus, the pressure-regulated vessel was capable of delivering 20 sccm of B₂F₄ at a dynamic delivery pressure of approximately 385 torr.

High voltage gap tests were conducted with the pressure-regulated vessel containing B₂F₄. This assessment involved adding different pressures into the voltage gap bulkhead 7 and isolating the dopant source gas supply vessel. The high voltage then was increased and breakdown was monitored via the leakage current. As shown in Table 2, no voltage breakdown occurred down to 390 torr and up to 40 keV.

TABLE 2

Extraction Current

| Extraction | Bulkhead | Bulkhead |
|---|---|---|
| Voltage (keV) | pressure = 460 torr | pressure = 390 torr |
| 5 | 0 | 0 |
| 10 | 0 | 0 |
| 15 | 0 | 0 |
| 20 | 0.2 | 0.2 |
| 25 | 0.3 | 0.3 |
| 30 | 0.4 | 0.4 |
| 34 | | 0.6 |
| 36 | | 0.6 |
| 38 | | 0.7 |
| 40 | | 0.7 |

While the disclosure has been described herein in reference to specific aspects, features and illustrative embodiments of the disclosure, it will be appreciated that the utility of the disclosure is not thus limited, but rather extends to and encompasses numerous other variations, modifications and alternative embodiments, as will suggest themselves to those of ordinary skill in the field of the present disclosure, based on the disclosure herein. Correspondingly, the invention as hereinafter claimed is intended to be broadly construed and interpreted, as including all such variations, modifications and alternative embodiments, within its spirit and scope.

1. A fluid supply system for delivery of fluid from a fluid supply source vessel at a relatively lower voltage to at least one fluid-utilizing tool at a relatively higher voltage wherein the fluid passes through a corresponding voltage differential, said fluid supply system comprising the fluid supply source vessel, and at least one fluid management apparatus selected from the group consisting of:
(a) a fluid delivery flow circuit comprising a fluid delivery line adapted for coupling to the fluid supply vessel to flow fluid from the fluid supply vessel through the voltage differential to the fluid-utilizing tool, a dielectric interface adapted for coupling to the fluid delivery line to separate lower voltage and higher voltage segments of the fluid delivery line from one another, a first pressure regulator and a flow control component or assembly in the lower voltage segment of the fluid delivery line, a second pressure regulator in the higher voltage segment of the fluid delivery line, wherein the first and second pressure regulators are adapted to regulate pressure of fluid flowed through the fluid delivery line from the fluid supply vessel to the fluid-utilizing tool to reduce pressure variation of fluid flowed to the fluid-utilizing tool;
(b) an electric current monitor adapted to monitor current in the fluid supply source vessel and output a signal correlative to said current in an event of electrical disturbance mediating arcing, discharge, or premature ionization of the fluid in a fluid delivery flow circuit when coupled to the fluid delivery source vessel, and an interlock system adapted to receive the signal from the electric current monitor in said event of electrical disturbance, and responsively actuate a remedial action to abate the electrical disturbance or ameliorate an effect thereof;
(c) a fluid delivery flow circuit comprising a non-linear fluid delivery line adapted for coupling to the fluid supply vessel, to provide a non-linear extended length flow path for flow of fluid from the fluid supply vessel through the voltage differential to a fluid-utilizing tool, to suppress arcing, discharge, or premature ionization of the fluid;
(d) a fluid delivery flow circuit comprising a fluid delivery line adapted for coupling to the fluid supply vessel to flow fluid from the fluid supply vessel through the voltage differential to the fluid-utilizing tool, the fluid delivery line being in fluid communication with a reversible sorbent medium having sorptive affinity for said fluid and arranged to sorptively/desorptively modulate fluid flow through the fluid delivery line to prevent fluid supply interruptions;
(e) a control system adapted to monitor and control supply pressure and/or the demand flow rate of fluid flowed from the fluid supply vessel to the fluid-utilizing tool to reduce pressure variation of fluid flowed to the fluid-utilizing tool;
(f) a thermal control system adapted to heat or cool fluid flowed from the fluid supply vessel to the fluid-utilizing tool, at sufficient rate to control fluid pressure so as to reduce pressure variation of fluid flowed to the fluid-utilizing tool;
(g) a fluid delivery flow circuit comprising a fluid delivery line adapted for coupling to the fluid supply vessel to flow fluid from the fluid supply vessel through the voltage differential to the fluid-utilizing tool, and a surge chamber coupled to the fluid delivery line and adapted to receive fluid from the fluid delivery line so as to provide a gas reservoir to prevent gas supply interruptions; and
(h) an on-board vessel associated with the fluid-utilizing tool and at the relatively higher voltage thereof during operation of the fluid-utilizing tool, said on-board vessel being adapted for filling by said fluid supply source vessel during said operation or between successive periods of said operation, and if adapted to be filled during said operation, then comprising at least one fluid management apparatus (a)-(g).

2. The fluid supply system of claim 1, wherein the fluid-utilizing tool comprises an ion implantation tool.

3. The fluid supply system of claim 2, wherein the fluid supply source vessel is outside of a housing of the ion implantation tool.

4. The fluid supply system of claim 1, wherein the fluid supply source vessel is remote from the fluid-utilizing tool.

5.-8. (canceled)

9. The fluid supply system of claim 1, comprising fluid management apparatus (a).

10. The fluid supply system of claim 9, further comprising a mass flow controller arranged to receive fluid that has been pressure regulated by the second pressure regulator and to modulate flow rate of fluid flowed to the fluid-utilizing tool.

11. (canceled)

12. The fluid supply system of claim 9, wherein each of the first pressure regulator and second pressure regulator is a variable set point regulator, and wherein the system comprises a monitoring and control assembly operative to dynamically modulate set points of one or both regulators in response to system operating conditions.

13. The fluid supply system of claim 9, wherein one of the first pressure regulator and second pressure regulator is a fixed set point regulator and the other regulator is a variable set point regulator.

14. The fluid supply system of claim 1, comprising fluid management apparatus (b).

15.-17. (canceled)

18. The fluid supply system of claim 1, comprising fluid management apparatus (c).

19. The fluid supply system of claim 18, wherein the non-linear fluid delivery line has a wave shape, a “Z” shape, a “S” shape, or a coil shape.

20. The fluid supply system of claim 1, comprising fluid management apparatus (d).

21.-23. (canceled)

24. The fluid supply system of claim 20, wherein multiple volumes of said reversible sorbent medium are provided in fluid communication with the fluid delivery line along its length.

25.-28. (canceled)

29. The fluid supply system of claim 1, comprising fluid management apparatus (e).

30. The fluid supply system of claim 29, wherein fluid management apparatus (e) comprises a mass flow controller in fluid delivery flow circuitry coupling the fluid supply vessel to the fluid-utilizing tool, and the fluid delivery flow circuitry comprises a bypass line through the mass flow controller that is controllably openable by the fluid management apparatus to a vent line, pump, or evacuated volume for prevention of pressure surge, and controllably closable by the fluid management apparatus in a manner suppressing said pressure variations.

31. The fluid supply system of claim 1, comprising fluid management apparatus (f).

32. The fluid supply system of claim 29, wherein the fluid management apparatus (f) comprises a temperature controller adapted to heat or cool at least part of fluid delivery flow circuitry coupling the fluid supply vessel to the fluid-utilizing tool to control said fluid pressure of the fluid flowed through said flow circuitry in a manner suppressing said pressure variations.

33. The fluid supply system of claim 1, comprising fluid management apparatus (g).

34. The fluid supply system of claim 33, wherein the fluid management apparatus (g) comprises a variable volume surge chamber.

35. (canceled)

36. The fluid supply system of claim 1, comprising fluid management apparatus (h).

37.-38. (canceled)

39. A method of delivering fluid at relatively lower voltage to at least one fluid-utilizing tool at relatively higher voltage, wherein the fluid passes through a corresponding voltage differential, said method comprising operating a fluid supply system according to claim 1.

40.-44. (canceled)

45. A method of providing fluid for use in a manufacturing facility comprising at least one fluid-utilizing tool operated at elevated voltage, said method comprising disposing a fluid supply system according to claim 1 in fluid supply relationship to the at least one fluid-utilizing tool in the manufacturing facility.

46.-47. (canceled)
